(19) United States
(12) Patent Application Publication
(10) Pub. No.: US 2021/0280765 A1
(43) Pub. Date: Sep. 9, 2021

(54) SUPERCONDUCTING CARRIER AND CABLES FOR QUANTUM DEVICE CHIPS AND METHOD OF FABRICATION

(71) Applicant: THE BOARD OF TRUSTEES OF THE UNIVERSITY OF ALABAMA, Tuscaloosa, AL (US)

(72) Inventor: Qiang Huang, Tuscaloosa, AL (US)

(21) Appl. No.: 17/132,032

(22) Filed: Dec. 23, 2020

Related U.S. Application Data
(60) Provisional application No. 62/986,221, filed on Mar. 6, 2020.

(51) Int. Cl. H01L 39/24; G06N 10/00; H01L 39/06; H01B 12/14

(52) U.S. Cl. CPC H01L 39/24; H01B 12/14; H01L 39/06; G06N 10/00

(57) ABSTRACT

A carrier is provided for quantum computer chips that allows easy implementation, connection, and communication to and from the quantum computer chips while minimizing the thermal perturbation and avoiding labor intensive manual connection as well as the human error in such manual connection. Methods for fabricating such carriers are also provided.

### CROSS-REFERENCE TO RELATED APPLICATIONS

This application claims the benefit of priority to U.S. Provisional Patent Application No. 62/986,221, filed on Mar. 6, 2020, entitled “SUPERCONDUCTING CARRIER AND CABLES FOR QUANTUM DEVICE CHIPS AND METHOD OF FABRICATION,” the contents of which are hereby incorporated by reference in their entirety.

### STATEMENT OF GOVERNMENT SUPPORT

This invention was made with government support under 1662332 and 1929549 awarded by the National Science Foundation (NSF). The government has certain rights in the invention.

### BACKGROUND

Cryogenic quantum computing devices (i.e., quantum computers) use quantum computer chips (i.e., qubit chips) comprising superconducting junctions (i.e., qubits) at extremely cold (e.g., cryogenic) temperatures. However, the inputs and outputs to the quantum computers come from external control units that operate at ambient temperatures. The electrical wires that provide the inputs and outputs between an external control unit and a quantum computer are typically meters long to go through different stages of refrigeration and travel between an ambient stage and a cryogenic stage.

The electrical wiring to cryogenic quantum computers is currently performed manually (i.e., with manual assembly) because the number of qubits in current quantum computers are typically in the single digits or lower double digits. For a quantum computer chip comprising 50 qubits, the wires are typically up to hundreds of meters long in total and need to be connected to each individual qubit (or more precisely the superconducting junction that provides the qubit). In addition, the wires have to be superconducting—at least for the bottom part of each wire that is close to the associated qubit—so that thermal perturbation due to the electrical heat from wires is avoided. As the number of qubits increases and the quantum computer chip layout becomes more complex, manual connection of all wires will become extremely complex and time consuming, and eventually impossible.

It is with respect to these and other considerations that the various aspects and embodiments of the present disclosure are presented.

### SUMMARY

A carrier is provided for quantum computer chips that allows easy implementation, connection, and communication to and from the quantum computer chips while minimizing the thermal perturbation and avoiding labor intensive manual connection as well as the human error in such manual connection. Methods for fabricating such carriers are also provided.

An implementation comprises a method of fabricating a carrier for quantum computer chips. The method comprises: forming at least one or more of holes, vias, voids, trenches, lines, or notches in an insulating substrate; depositing a superconducting layer on the insulating substrate in at least one of the holes, vias, voids, trenches, lines, or notches; and encapsulating the superconducting layer with an insulator.

An implementation comprises a deposition method that comprises: depositing a superconducting layer on at least a portion of a seed layer, using at least one electrodeposition technique, wherein the at least one electrodeposition technique deposits at least one of vanadium, tin, indium, gallium, lead, rhenium, and the alloys of thereof, and rhenium alloys with other elements comprising at least one of molybdenum, iron, cobalt, or nickel.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIG. 1 is an illustration of exemplary quantum computers, without and with electrical wires;

FIGS. 2A, 2B, and 2C are illustrations of example uses of carriers, interconnects, and cables;

FIG. 3 is an illustration of example images of carriers, interconnects, and cables;

FIG. 4A is a diagram of an implementation of a method of fabrication of a cable for quantum computer chips;

FIG. 4B is a diagram of an implementation of a continuous process of fabrication;

FIG. 5 is an operational flow of an implementation of a method of fabricating a cable or carrier for quantum computer chips;

FIGS. 6A-6F are diagrams of another implementation of a method of fabrication of a carrier for quantum computer chips;

FIGS. 7A-7D are diagrams of another implementation of a method of fabrication of a carrier for quantum computer chips;

FIGS. 8A and 8B are diagrams of another implementation of a method of fabrication of a carrier for quantum computer chips;

FIGS. 9A, 9B, and 9C are diagrams of another implementation of a method of fabrication of a carrier for quantum computer chips; and

FIGS. 10A, 10B, and 10C are diagrams of another implementation of a method of fabrication of a carrier for quantum computer chips.

### DETAILED DESCRIPTION

The description is not to be taken in a limiting sense, but is made merely for the purpose of illustrating the general principles of the invention, since the scope of the invention is best defined by the appended claims.

Various inventive features are described herein that can each be used independently of one another or in combination with other features.

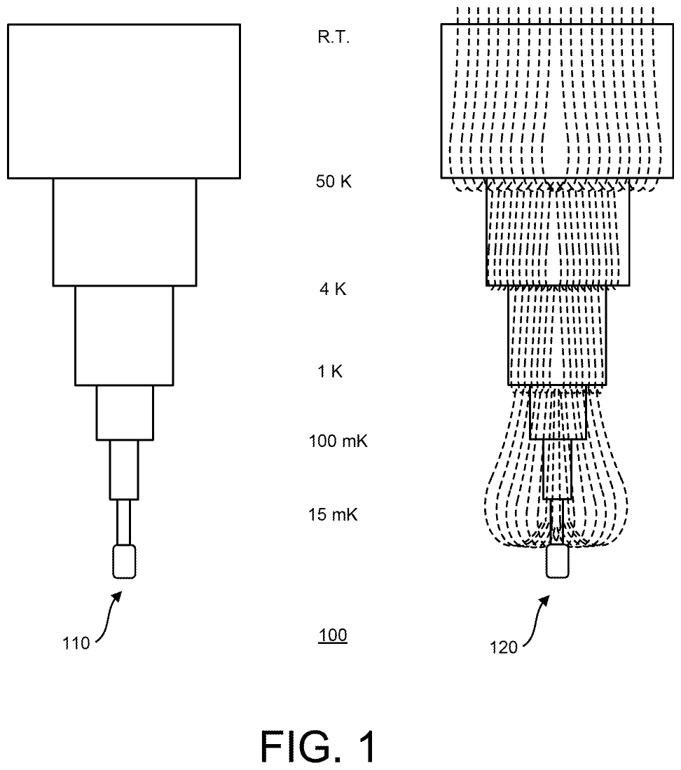

FIG. 1 is an illustration of exemplary quantum computers 110 and 120, without and with electrical wires, respectively. A quantum computer is controlled by control units, which may be at room temperature (R.T.) or any intermediately low temperatures and the quantum computer goes through different stages of refrigeration down to an extremely cryogenic stage (e.g., passing through 50 K, 4 K, 1 K, 100 mK, down to 15 mK), where the quantum processor is placed. The quantum computer 110 is shown without the wires used to provide the inputs and outputs to control units and quantum processor, and the quantum computer 120 is shown with the wires used to provide the inputs and outputs to control units and quantum processor. As shown, the electrical wires in the arrangement of the computer quantum 120 are long and densely and precisely arranged. As one embodiment described further herein, techniques, such as electrodeposition, are used to fabricate superconducting cables to replace such wires.

The wirings in FIG. 1 also provide communication between multiple quantum device chips, and between quantum device chip and other device chips at extremely cryogenic temperatures, if needed. As another embodiment described further herein, techniques, such as electrodeposition, are used to fabricate superconducting chip carriers to replace such wires and enable communication between a large number of quantum device chips and other chips at extremely cryogenic temperatures.

Superconducting wirings fabricated on a quantum device chip are also needed to enable communication between multiple qubits (junction devices) within a single chip. Such wirings have been fabricated using lithography patterning, vacuum deposition and dry etching techniques. As yet another embodiment described further herein, techniques, such as electrodeposition, are used to fabricate superconducting interconnects on quantum chip to enable communication between a large number of qubits within a chip at extremely cryogenic temperature.

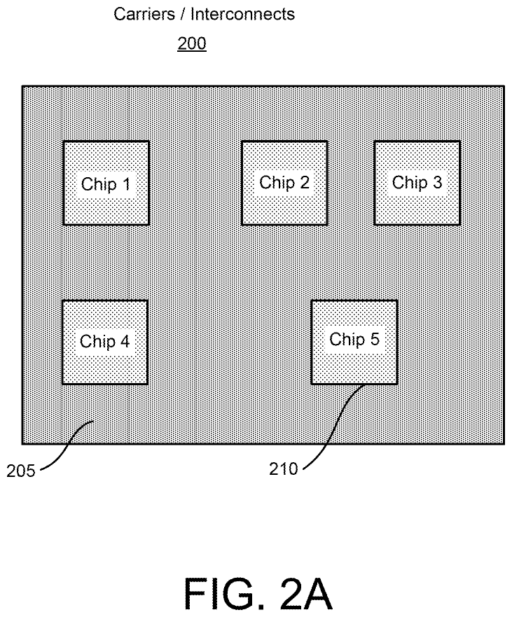

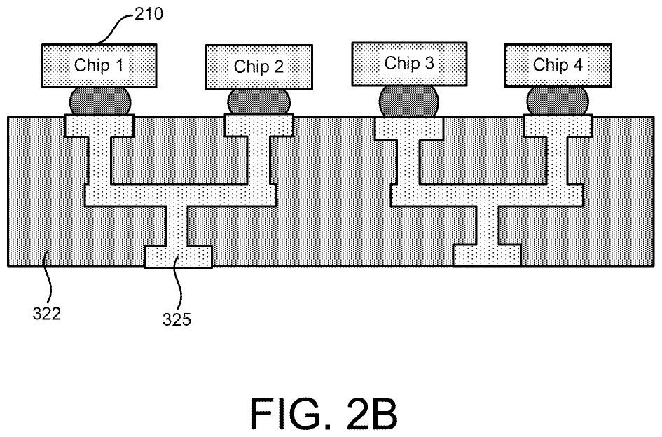

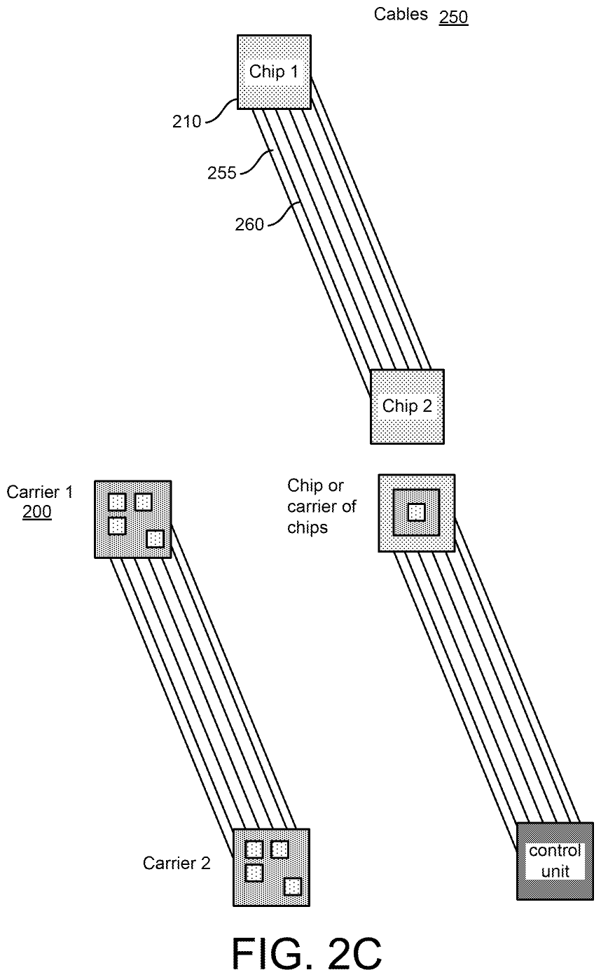

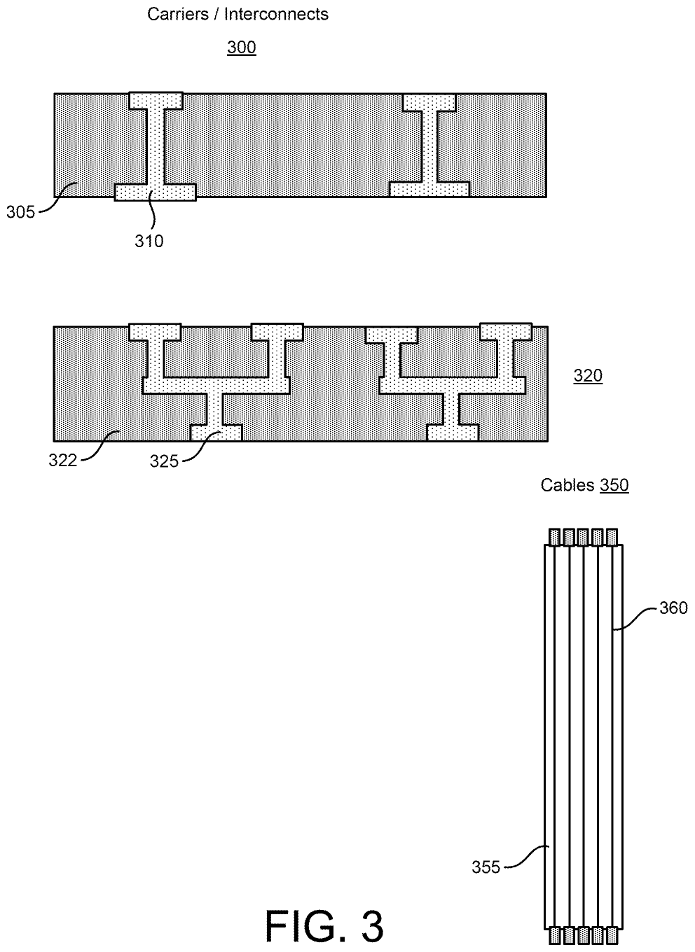

FIGS. 2A, 2B, and 2C are illustrations of example uses of carriers, interconnects, and cables. A top down view of a carrier 200 is shown in FIG. 2A, where various quantum device chips or other cryogenic device chips 210 have been attached on the carrier 200. The carrier 200 comprises an insulator 205 (e.g., silicon oxides, aluminum oxides, glass, ceramics, plastics, nylon, polyimide, PVC, other organic polymers etc.) and superconducting wirings in the insulator. The chips 210 may be connected with each other through the carrier 200 with the superconducting wirings disposed (e.g., deposited) in the insulator 205 (similar to the superconducting materials 310, 325 deposited in the insulators 305, 322, respectively of FIG. 3).

As shown in the cross sectional diagram in FIG. 2B, the chips 210 may be bonded to superconducting materials 325 disposed in an insulator 322 (described further with respect to FIG. 3)

As shown in FIG. 2C, one or more of the quantum computer chips 210 (e.g., Chip 1) may be connected to one or more other of the quantum computer chips 210 (e.g., Chip 2) using one or more cables 250. One or more of the carriers 200 with chip stacks 210 (e.g., Carrier 1) may be connected to one or more other of the stacks 200 (e.g. Carrier 2) using one or more cables 250. Furthermore, one or more of the quantum device chips 210 or one or more of the carriers 200 can be connected to other control units at cryogenic temperatures or at room temperatures using one or more cables 250. Each cable 250, like the cable 350, comprises an insulator 255 (such as plastic, nylon, polyimide, PVC, or any bendable insulating material, etc.) and superconducting wires 260.

The carriers and cables described and contemplated herein for quantum computer chips allow easy implementation, connection, and communication between quantum device chips, to and from the quantum computer chips while minimizing the thermal perturbation and avoiding labor intensive manual connection as well as the human error in such manual connection.

A carrier or cable comprises an electrically non-conductive substrate and superconducting wirings fabricated on the substrate or in the substrate. One side (end) of such wirings connects to one or more quantum devices or other cryogenic devices. The other side (end) connects to same or different type of devices, or to input/output communication wires from external control units. The two sides (ends) can have different dimensions to fit the connected parts. Such carriers can be connected in series; in other words, one carrier can be connected to another to form a multi-stage carrier connections. The carrier may have multiple layers of superconducting wires to allow point to point communication without crossing. The substrate comprises good thermal insulating materials to allow better thermal isolation between different frigerated or cryogenic chambers. The multi-layers of superconducting wires can be fabricated using techniques such as electrochemical deposition, chemical vapor deposition, physical vapor deposition, evaporation, lithography, electrochemical 3D printing, etc., for example.

The superconducting wires in a carrier can also penetrate the substrate, reaching both sides of the substrate. One side of the carrier will connect to the quantum chip and the other side with same or other device chips, connection wires, connection socket, or another carrier.

FIG. 3 is an illustration of example images of carriers, interconnects, and cables. A carrier 300 is shown comprising an insulator 305 (e.g., silicon oxides, aluminum oxides, glass, ceramics, plastics, nylon, polyimide, PVC, other organic polymers, etc.) with a superconducting material 310 disposed therein. A carrier 320 is shown comprising an insulator 322 and a superconducting material 325 disposed therein. The insulators 305 and 322 may be patterned with holes (i.e., voids) formed (e.g., by etching, drilling, etc.) into which the superconducting materials 310, 325 may be deposited (e.g., by electrodeposition or any other deposition technique(s)). One or more layers of insulators and superconducting materials may be used, with associating patterning and hole formation. Although only up to two layers and two pairs of superconducting wires 310, 325 are shown, this is not intended to be limiting, and the number of layers and number of superconducting wires that may be implemented is without limit dependent on the quantum computer arrangement.

A cable 350 comprises an insulator 355 (such as plastic, nylon, polyimide, PVC, or any bendable insulating material, etc.) and superconducting wires 360. The superconducting wires 360 may replace the conventional wires that otherwise would have to be manually connected between the control units and the quantum device chips and other cryogenic device chips, or between the chips themselves. These superconducting wires 360 may be disposed within cables 350 that may be easily connected between components of a quantum computer, as well as between the control units and the quantum computer. Although only five superconducting wires 360 are shown, this is not intended to be limiting, and the number of superconducting wires that may be implemented is without limit dependent on the quantum computer arrangement.

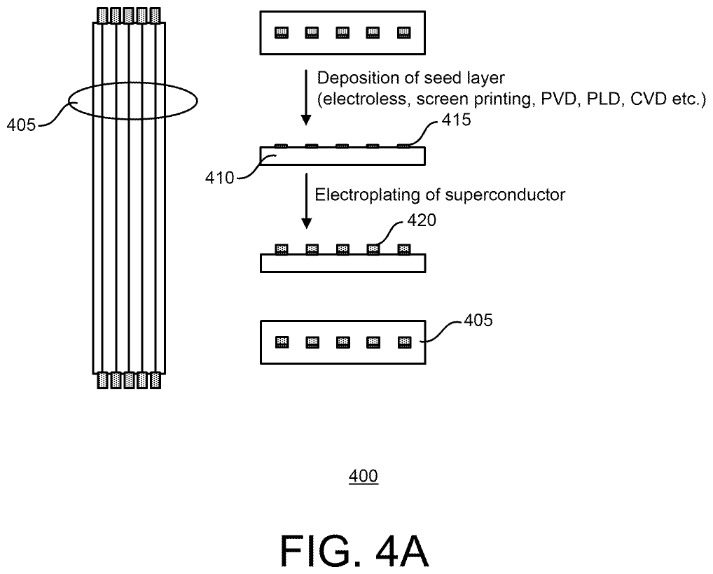

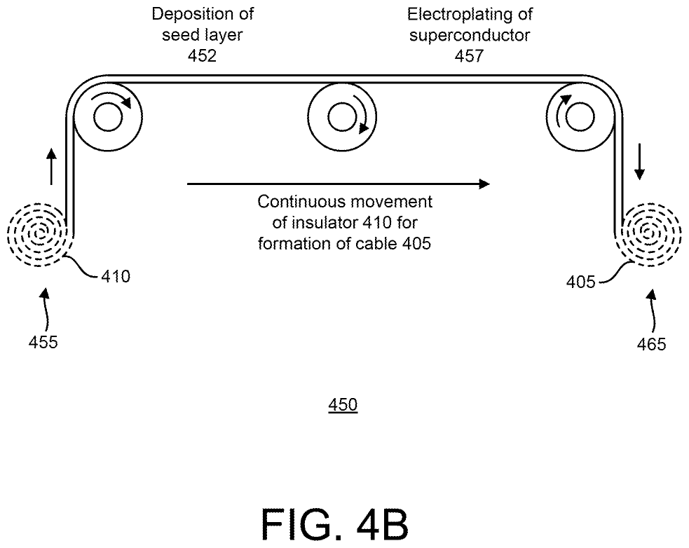

FIG. 4A is a diagram of an implementation of a method 400 of fabrication of a cable, such as cable 405, for quantum computer chips. Here, a cable 405 comprises bendable insulators and superconducting wires (similar to the cables 250, 350, for example). A seed layer 415 (such as metal contacts) is deposited on an insulator 410 (e.g., an insulating substrate, plastic, nylon, polymer, insulating material, etc.) using any known technique such as electroless, screen printing, direct writing, physical vapor deposition (PVD), pulsed laser deposition (PLD), chemical vapor deposition (CVD), etc., for example.

A superconducting layer 420 is depositing on the seed layer 415, e.g., using electroplating or electrodeposition, for example, through any deposition technique may be used depending on the implementation. For another example, through electrodeposition techniques to deposit vanadium, tin, indium, gallium, lead, rhenium, and the alloys of thereof, and rhenium alloys with other elements such as for example, molybdenum, iron, cobalt, nickel. For further another example, the electrodeposition technique employs electrolytes comprising at least a solute of a concentration of at least 1 M, and preferably at least 3 M, and further preferably at least 5 M, as disclosed in application with U.S. patent application Ser. No. 16/722,237, filed on Dec. 20, 2019, and entitled “Methods For Electrodeposition,” the disclosure of which is expressly incorporated herein by reference in its entirety. A layer of insulator 425 may then be deposited thereon, to encapsulate some or all of the seed layer 415 and the superconducting layer 420.

FIG. 4B is a diagram of an implementation of a continuous process 450 of fabrication. In some implementations, the process 450 may utilize the method 400 of FIG. 4A. More particularly, FIG. 4B represents an exemplary roll-to-roll process to fabricate superconducting cable. The starting materials on the left 455 of FIG. 4B is a roll of insulating substrate (e.g., the insulator 410 of FIG. 4A in a bendable and/or rollable form), and the end product on the right 465 of FIG. 4B is the cable (e.g., the cable 405 of FIG. 4B) with seed later and superconducting material on the insulating substrate. This process allows a continuous production of such cables.

In the process 450, where the insulating substrate is bendable, it may move in a continuous fashion as it is unrolled from the left 455 of FIG. 4B and rolled onto the right 465 of FIG. 4B. The holes, the seed layer 452, and the superconducting layer 457 can be deposited sequentially as the insulating substrate moves in the continuous fashion.

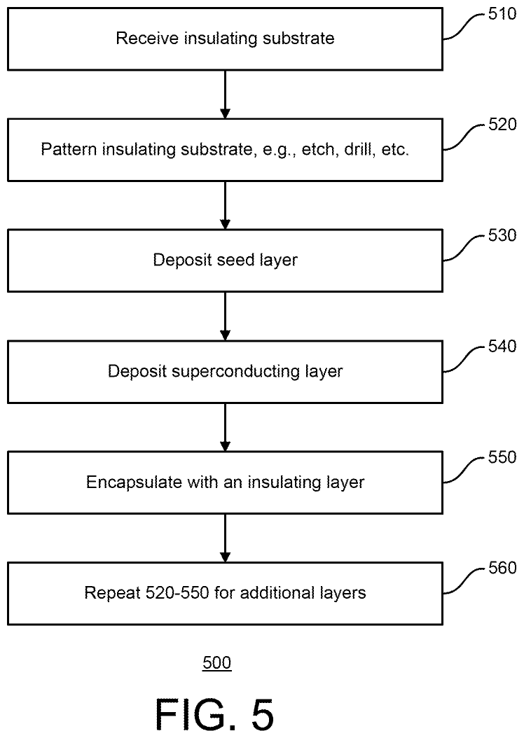

FIG. 5 is an operational flow of an implementation of a method 500 of fabricating a carrier for quantum computer chips. At 510, an insulating substrate (e.g., an insulator such as the insulator 205, 305, 322) is received. The insulating substrate is patterned at 520, by etching, drilling, etc. (or otherwise removing a portion of the insulating substrate) to form one or more holes, vias, voids, notches, etc., for example therein.

At 530, a seed layer (e.g., metal contacts) is deposited, similar to the seed layer 415 for example. It is contemplated that this step is optional, as some implementations may not use or incorporate a seed layer.

At 540, a superconducting layer is deposited, similar to the superconducting layer 420. Encapsulation of some or all of the layers is performed by deposition of an insulating layer thereon, at 550. Steps 520-550 may be repeated, as desired depending on the implementation, to fabricate additional seed layers, superconducting layers, and/or insulating layers.

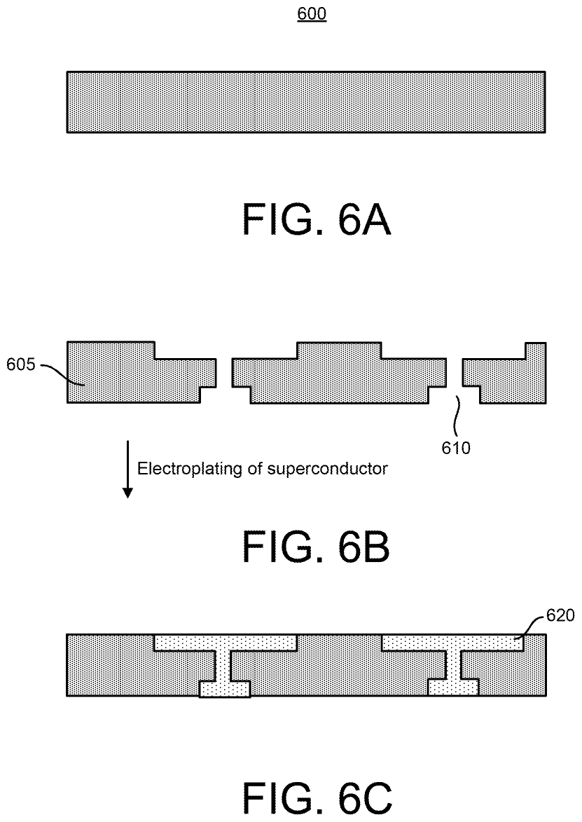

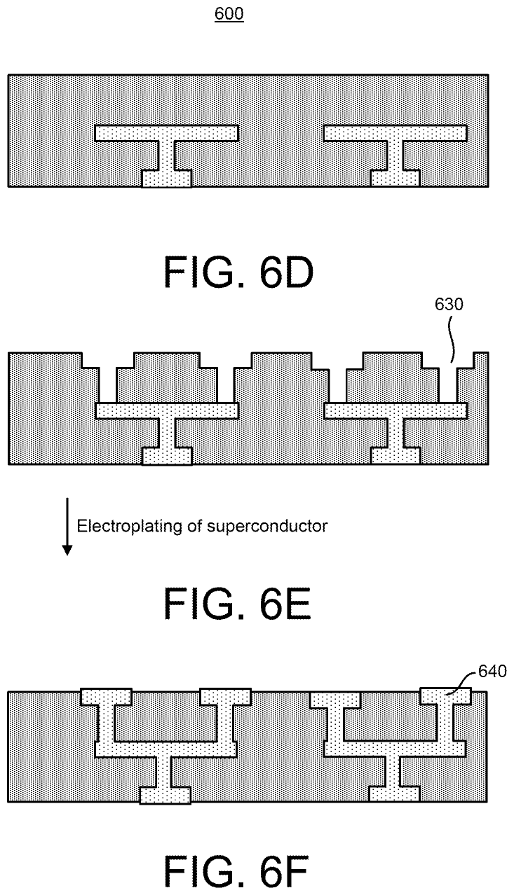

FIGS. 6A-6F are diagram of another implementation of a method 600 of fabrication of a carrier for quantum computer chips. An insulator 605 is received or otherwise formed (FIG. 6A), and holes, vias, voids, trenches, lines, and/or notches 610 are formed (FIG. 6B) e.g., using patterns, drilling, etching, etc. Any known technique for patterning and hole, via, void, notch formation may be used.

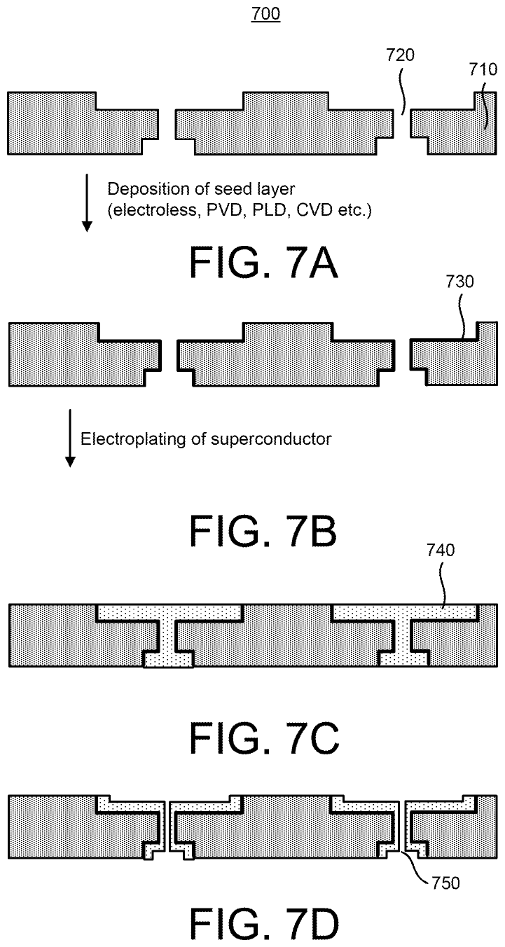

A superconducting layer 620 may be deposited in the holes, vias, voids, and/or notches (FIG. 6C), using electrodeposition with details described with respect to FIGS. 7A-7D, for example. An additional insulating layer may be deposited thereon (FIG. 6D). Further patterning and formation of holes, vias, voids, trenches, lines, and/or notches 630 may be performed (FIG. 6E), followed by additional electroplating of superconductor to deposit additional superconducting layers 640 (FIG. 6F).

FIGS. 7A-7D are diagrams showing the details of a method 700 of superconductor electroplating or electrodeposition in FIG. 6C of the fabrication of a carrier for quantum computer chips. An insulator 710 is received or otherwise formed, and holes, vias, voids, trenches, lines, and/or notches 720 are formed (FIG. 7A) e.g., using patterns, drilling, etching, etc. Any known technique for patterning and hole, via, void, notch formation may be used.

A seed layer 730 is deposited on the surfaces of the insulator 710 exposed during the patterning, drilling, etching, etc. using any known technique(s) such as PVD (physical vapor deposition), PLD (pulse laser deposition), CVD (chemical vapor deposition), electroless deposition, etc. (FIG. 7B). A superconducting layer may be deposited in the holes, vias, voids, trenches, lines, and/or notches over the seed layer 730. The deposited superconductor can form a thin layer of superconductor 750 on the seed layer 730 in the holes, vias, voids, trenches, lines, and/or notches (FIG. 7D), or form a continuous superconductor structure 740 that completely fills the holes, vias, voids, trenches, lines, and/or notches (FIG. 7C). The superconductor 740 and 750 can be deposited in a similar way as 420. An additional but optional etching process can be used to partially remove the seed layer or the superconductor materials.

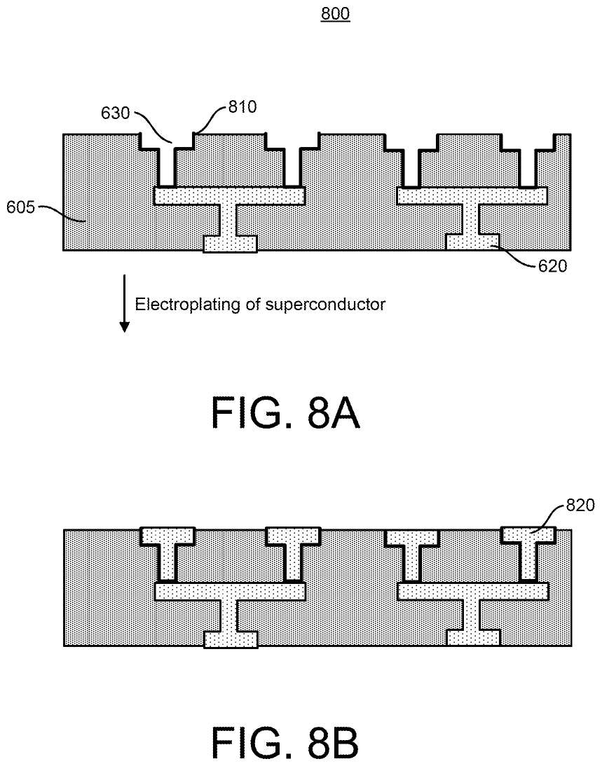

FIGS. 8A and 8B are diagrams of another implementation of a method 800 of fabrication of a carrier for quantum computer chips. Here, the method continues after FIG. 6E. A seed layer 810 is deposited on some or all of the surfaces of the superconducting layer 620 exposed during the patterning, drilling, etching, etc. of the insulator 605 using any known technique(s) such as electroless, PVD, PLD, CVD, etc. (FIG. 8A). A superconducting layer 820 may then be deposited in the holes, vias, voids, and/or notches over the seed layer 810 (FIG. 8B).

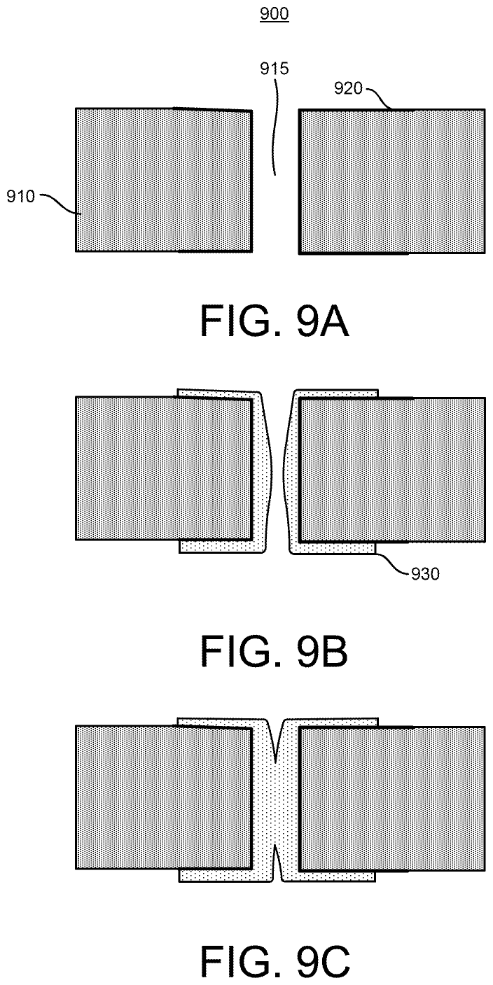

FIGS. 9A, 9B, and 9C are diagrams of another implementation of a method 900 of fabrication of a carrier for quantum computer chips. An insulator 910 is drilled (or otherwise patterned) to form a hole, via, void, trenches, lines, or notch 915, and a seed layer 920 is deposited on some or all parts of the insulator 910 exposed by the drilling or patterning (FIG. 9A). The seed layer 920 may also be deposited on some or all parts of the insulator 910 that were not exposed by the drilling or patterning.

Electrodeposition of a superconductor is performed to deposit a superconducting layer 930 on some or all of the seed layer 920 (FIG. 9B), in a similar way as 420. For example, through electrodeposition techniques to deposit vanadium, tin, indium, gallium, lead, rhenium, and the alloys of thereof, and rhenium alloys with other elements such as for example, molybdenum, iron, cobalt, nickel. For example, electrodeposition techniques employ electrolytes comprising at least a solute of a concentration of at least 1 M, and preferably at least 3 M, and further preferably at least 5 M, as disclosed in U.S. patent application Ser. No. 16/722,237. For another example, electrodeposition techniques employ electrolytes comprising at least 5 M lithium chloride, and rhenium salt to a desired concentration. For yet another example, electrodeposition techniques employs electrolytes further comprising at least an organic molecule to modulate the deposition rate, such as nitrogen, sulfur, phosphorous containing compounds, including ammonium salts, tetraalkylammonium salts, dioxime, polyalkylene glycol, polyalkylene imine, saccharin, thiourea, sulfonic acid and its salts, sulfinic acid and its salts. Electrodeposition may continue until the superconduct layer 930 has a desired thickness and/or profile (FIG. 9C). An additional but optional etching process can be used to partially remove the seed layer or the superconductor materials.

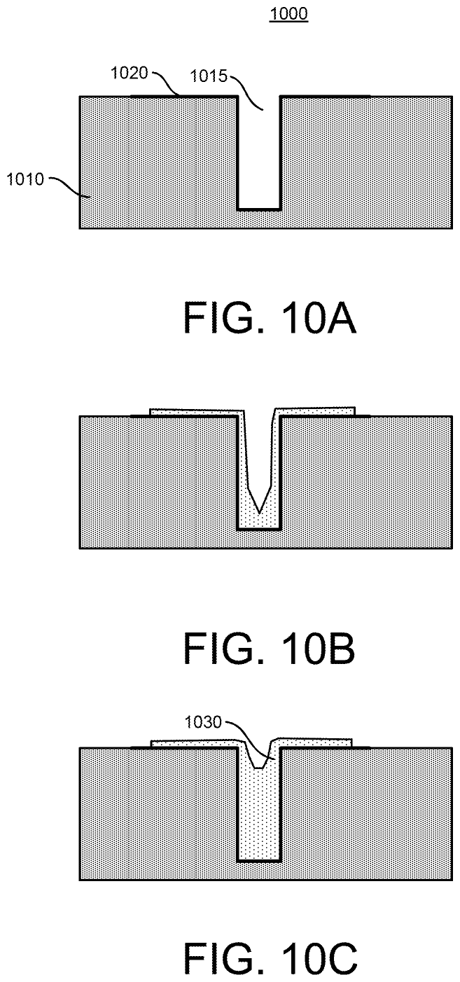

FIGS. 10A, 10B, and 10C are diagrams of another implementation of a method 1000 of fabrication of a carrier for quantum computer chips. Similar to FIG. 9A, an insulator 1010 is drilled (or otherwise patterned) to form a hole, via, void, or notch 1015, and a seed layer 1020 is deposited on some or all parts of the insulator 1010 exposed by the drilling or patterning (FIG. 10A). The seed layer 1020 may also be deposited on some or all parts of the insulator 1010 that were not exposed by the drilling or patterning.

Electrodeposition of a superconductor is performed to deposit a superconducting layer 1030 on some or all of the seed layer 1020 (FIG. 10B), in a similar way as 930. Electrodeposition may continue until the superconducting layer 1030 has a desired thickness and/or profile (FIG. 10C). An additional but optional etching process can be used to partially remove the seed layer or the superconductor materials.

In an implementation, a method of fabricating a carrier for quantum computer chips comprises: forming at least one or more of holes, vias, voids, trenches, lines, or notches in an insulating substrate; depositing a superconducting layer on the insulating substrate in at least one of the holes, vias, voids, trenches, lines, or notches; and encapsulating the superconducting layer with an insulator.

Implementations may include some or all of the following features. Forming the holes, vias, voids, or notches comprises at least one of patterning the insulating substrate, etching the insulating substrate, or drilling the insulating substrate. The method further comprises depositing a seed layer between the insulating substrate and the superconducting layer, prior to depositing the superconducting layer. The seed layer comprises a metal contact layer. The seed layer is deposited by at least one of an electroless technique, a screen printing technique, a physical vapor deposition (PVD) technique, a pulsed laser deposition (PLD) technique, or a chemical vapor deposition (CVD) technique. The insulating substrate is bendable, and the method further comprises moving the insulating substrate in a continuous fashion, wherein forming the at least one or more of holes, vias, voids, trenches, lines, or notches, depositing the seed layer, and depositing the superconducting layer are performed sequentially. The insulating substrate comprises at least one of silicon oxide, aluminum oxide, ceramics, glasses, plastics, nylon, polyimide, PVC, or other polymers. The superconducting layer is deposited by electrodeposition or electroplating. Depositing the superconducting layer on at least one of the holes, vias, voids, trenches, lines, or notches forms at least one superconducting wire. The at least one superconducting wire is configured to provide at least one of an input or an output to a quantum computer. The at least one superconducting wire is configured to provide at least one of an input or an output to a control unit of a quantum computer. The at least one superconducting wire is comprised within a carrier that connects components of a quantum computer. The method further comprises forming one or more additional holes, vias, voids, or notches in the insulator or the insulating substrate; and depositing another superconducting layer on the insulator or the insulating substrate in at least one of the additional holes, vias, voids, or notches. The method further comprises depositing another seed layer on the insulator or the insulating substrate in at least one of the additional holes, vias, voids, or notches, prior to depositing the another superconducting layer.

In an implementation, a deposition method comprises: depositing a superconducting layer on at least a portion of a seed layer, using at least one electrodeposition technique, wherein the at least one electrodeposition technique deposits at least one of vanadium, tin, indium, gallium, lead, rhenium, and the alloys of thereof, and rhenium alloys with other elements comprising at least one of molybdenum, iron, cobalt, or nickel.

Implementations may include some or all of the following features. The at least one electrodeposition technique employs electrolytes comprising at least a solute of a concentration of at least 1 M. The at least one electrodeposition technique employs electrolytes comprising at least a solute of a concentration of at least 3 M. The at least one electrodeposition technique employs electrolytes comprising at least a solute of a concentration of at least 5 M. The at least one electrodeposition technique employs electrolytes comprising at least 5 M lithium chloride, and rhenium salt to a desired concentration. The at least one electrodeposition technique employs electrolytes further comprising at least an organic molecule to modulate the deposition rate. The at least an organic molecule is one of nitrogen, sulfur, phosphorous containing compounds, ammonium salts, tetraalkylammonium salts, dioxime, polyalkylene glycol, polyalkylene imine, saccharin, thiourea, sulfonic acid and its salts, or sulfinic acid and its salts.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method of fabricating a carrier for quantum computer chips, the method comprising:
forming at least one or more of holes, vias, voids, trenches, lines, or notches in an insulating substrate;
depositing a superconducting layer on the insulating substrate in at least one of the holes, vias, voids, trenches, lines, or notches; and
encapsulating the superconducting layer with an insulator.

2. The method of claim 1, wherein forming the holes, vias, voids, or notches comprises at least one of patterning the insulating substrate, etching the insulating substrate, or drilling the insulating substrate.

3. The method of claim 1, further comprising depositing a seed layer between the insulating substrate and the superconducting layer, prior to depositing the superconducting layer.

4. The method of claim 3, wherein the seed layer comprises a metal contact layer.

5. The method of claim 3, wherein the seed layer is deposited by at least one of an electroless technique, a screen printing technique, a physical vapor deposition (PVD) technique, a pulsed laser deposition (PLD) technique, or a chemical vapor deposition (CVD) technique.

6. The method of claim 3, wherein the insulating substrate is bendable, further comprising moving the insulating substrate in a continuous fashion, wherein forming the holes, vias, voids, trenches, lines, or notches, depositing the seed layer, and depositing the superconducting layer are performed sequentially.

7. The method of claim 1, wherein the insulating substrate comprises at least one of silicon oxide, aluminum oxide, ceramics, glasses, plastics, nylon, polyimide, PVC, or other polymers.

8. The method of claim 1, wherein the superconducting layer is deposited by electrodeposition or electroplating.

9. The method of claim 1, wherein depositing the superconducting layer on at least one of the holes, vias, voids, trenches, lines, or notches forms at least one superconducting wire.

10. The method of claim 8, wherein the at least one superconducting wire is configured to provide at least one of an input or an output to a quantum computer or to a control unit of the quantum computer.

11. The method of claim 8, wherein the at least one superconducting wire is comprised within a carrier that connects components of a quantum computer.

12. The method of claim 1, further comprising:
forming one or more additional holes, vias, voids, or notches in the insulator or the insulating substrate; and
depositing another superconducting layer on the insulator or the insulating substrate in at least one of the additional holes, vias, voids, or notches.

13. The method of claim 12, further comprising depositing another seed layer on the insulator or the insulating substrate in at least one of the additional holes, vias, voids, or notches, prior to depositing the another superconducting layer.

14. A deposition method comprising:
depositing a superconducting layer on at least a portion of a seed layer, using at least one electrodeposition technique, wherein the at least one electrodeposition technique deposits at least one of vanadium, tin, indium, gallium, lead, rhenium, and the alloys of thereof, and rhenium alloys with other elements comprising at least one of molybdenum, iron, cobalt, or nickel.

15. The deposition method of claim 14, wherein the at least one electrodeposition technique employs electrolytes comprising at least a solute of a concentration of at least 1 M.

16. The deposition method of claim 14, wherein the at least one electrodeposition technique employs electrolytes comprising at least a solute of a concentration of at least 3 M.

17. The deposition method of claim 14, wherein the at least one electrodeposition technique employs electrolytes comprising at least a solute of a concentration of at least 5 M.

18. The deposition method of claim 14, wherein the at least one electrodeposition technique employs electrolytes comprising at least 5 M lithium chloride, and rhenium salt to a desired concentration.

19. The deposition method of claim 14, wherein the at least one electrodeposition technique employs electrolytes further comprising at least an organic molecule to modulate the deposition rate.

20. The deposition method of claim 19, wherein the at least an organic molecule is one of nitrogen, sulfur, phosphorous containing compounds, ammonium salts, tetraalkylammonium salts, dioxime, polyalkylene glycol, polyalkylene imine, saccharin, thiourea, sulfonic acid and its salts, or sulfinic acid and its salts.
